(19) United States
(12) Patent Application Publication
(10) Pub. No.: US 2011/0304763 A1
(43) Pub. Date: Dec. 15, 2011

(54) IMAGE SENSOR CHIP AND CAMERA MODULE HAVING THE SAME

(75) Inventors: Mi-Na Choi, Seoul (KR); Kyoung-Sei Choi, Yongin-si (KR); Hee-Seok Lee, Yongin-si (KR); Yong-Hoon Kim, Suwon-si (KR); Hee-Jung Hwang, Suwon-si (KR); Se-Ran Bae, Yongin-si (KR)

(73) Assignee: SAMSUNG ELECTRONICS CO., LTD., Suwon-si (KR)

(21) Appl. No.: 13/095,155

(22) Filed: Apr. 27, 2011

(30) Foreign Application Priority Data
Jun. 11, 2010 (KR) 10-2010-0055668

(51) Int. Cl. H04N 5/225; H01L 31/0216

(52) U.S. Cl. 348/340; 257/435; 257/E31.121; 348/E05.025

(57) ABSTRACT

An image sensor chip, a camera module, and devices incorporating the image sensor chip and camera module include a light receiving unit on which light is incident, a logic unit provided to surround the light receiving unit, and an electromagnetic wave shielding layer formed on the logic unit and not formed on the light receiving unit.

### CROSS-REFERENCE TO RELATED APPLICATION

This application claims priority under 35 U.S.C. 119 from Korean Patent Application No. 10-2010-0055668 filed on Jun. 11, 2010 in the Korean Intellectual Property Office, the entire contents of which are herein incorporated by reference.

### BACKGROUND OF THE INVENTION

1. Field of the Invention

The present inventive concept relates to an image sensor chip and a camera module having the same.

2. Description of the Related Art

Electronic devices such as mobile phones and portable digital cameras are typically designed to have a camera function. Accordingly, recently there is increasing demand for a subminiature and high image quality camera module. The camera module may include an image sensor chip having a CMOS image sensor or CCD image sensor, and a lens unit disposed on the image sensor chip and having at least one lens.

There are many factors that may reduce performance of the camera module. For example, electromagnetic waves external to the camera module may interfere with the camera module, and, as a result, cause malfunction of the camera module, such as by degradation of image quality. Specifically, in a case where external electromagnetic waves are introduced into the camera module without filtration, electromagnetic interference (EMI) may occur. One effect of EMI is that the image sensor chip malfunctions due to disturbance caused by the electromagnetic waves.

In some conventional camera modules, the effects of EMI are reduced by covering the camera module with a metal cap, or an electromagnetic wave shielding material is applied as a coating on a printed circuit board (PCB) of the camera module, or a tape which includes an electromagnetic shielding material is applied to the PCB.

### SUMMARY OF THE INVENTION

The present inventive concept provides an image sensor chip capable of shielding electromagnetic radiation inputted/outputted through a lens unit.

The present inventive concept also provides a camera module capable of shielding electromagnetic radiation inputted/outputted through a lens unit.

The present inventive concept also provides a mobile telephone which includes a camera function, the mobile telephone shielding electromagnetic radiation such that degradation in image quality due to EMI is reduced or eliminated.

The present inventive concept also provides a digital camera, the digital camera shielding electromagnetic radiation such that degradation in image quality due to EMI is reduced or eliminated.

The present inventive concept also provides a digital video camera, the digital video camera shielding electromagnetic radiation such that degradation in image quality due to EMI is reduced or eliminated.

The present inventive concept also provides a portable notebook computer which includes a camera function, the portable notebook computer shielding electromagnetic radiation such that degradation in image quality due to EMI is reduced or eliminated.

The present inventive concept also provides methods of manufacturing the image sensor chip, the camera module, the mobile telephone, the digital camera, the digital video camera and the portable notebook computer.

According to an aspect of the present inventive concept, there is provided an image sensor chip including a light receiving unit, a logic unit, and an electromagnetic wave shielding layer. The light receiving unit is formed in the image sensor chip and is adapted to receive incident light. The logic unit is formed in the image sensor ship and is formed to surround the light receiving unit. The electromagnetic wave shielding layer is formed on the logic unit to surround the logic unit and to be absent from a region of the image sensor chip above the light receiving unit.

In some embodiments, the electromagnetic wave shielding layer comprises a soft magnetic material. The soft magnetic material may include ferrite. The ferrite may include at least one of Mn—Zn ferrite and Ni—Zn ferrite.

In some embodiments, the electromagnetic wave shielding layer comprises metal powder. The metal powder may include powder of any material selected from the group consisting of titanium (Ti), chromium (Cr), titanium tungsten (TiW), aluminum (Al), nickel (Ni), copper (Cu), silver (Ag), and an alloy thereof.

In some embodiments, the electromagnetic wave shielding layer has opaqueness.

In some embodiments, the image sensor chip further comprises connection pads arranged at an edge portion of the logic unit. The electromagnetic wave shielding layer may expose the connection pads.

In some embodiments, the electromagnetic wave shielding layer is formed by applying a material for forming an electromagnetic wave shielding layer as a coating on the logic unit.

In some embodiments, electromagnetic wave shielding layer is formed by attaching a film made of a material for forming an electromagnetic wave shielding layer onto the logic unit.

According to another aspect of the present inventive concept, there is provided a camera module including a lens unit including a lens, and an image sensor chip which includes a light receiving unit configured such that light passing through the lens unit is incident on the light receiving unit, a logic unit provided to surround the light receiving unit, and an electromagnetic wave shielding layer formed on the logic unit to surround the logic unit and to be absent from a region of the image sensor chip above the light receiving unit.

In some embodiments, the electromagnetic wave shielding layer comprises a soft magnetic material.

In some embodiments, the electromagnetic wave shielding layer comprises metal powder.

In some embodiments, the camera module further comprises a housing enclosing side surfaces of the lens unit and the image sensor chip.

In some embodiments, the camera module further comprises a metal cover enclosing the housing.

In some embodiments, the camera module further comprises a printed circuit board on which the image sensor chip is mounted. In some embodiments, the printed circuit board is a rigid flexible printed circuit board (rigid FPCB) including a rigid region and a flexible region. In some embodiments, the image sensor chip is electrically connected to the printed circuit board by wire bonding.

In some embodiments, the camera module further comprises a connector attached to the printed circuit board.

According to another aspect of the inventive concept, there is provided a portable electronic device with a camera. The device includes an opening for allowing light to pass into the camera, a camera module for receiving the light, a processor for performing data processing on an image captured by the camera module, and a memory unit in communication with the processor for storing data of the image. The camera module includes a lens through which the light passes and an image sensor chip, the light passing through the lens being incident on the image sensor chip. The image sensor chip includes a light receiving unit on which the light is incident, a logic unit surrounding the light receiving unit, and an electromagnetic wave shielding layer formed on the logic unit to surround the logic unit and to be absent from a region of the image sensor chip above the light receiving unit;

In some embodiments, the portable electronic device further comprises an input/output device in communication with the processor for exchanging the data with an external device.

In some embodiments, the portable electronic device is a cellular telephone. In some embodiments, the portable electronic device is a digital camera. In some embodiments, the portable electronic device is a digital video camera. In some embodiments, the portable electronic device is a portable notebook computer.

### BRIEF DESCRIPTION OF THE DRAWINGS

The foregoing and other features and advantages of the inventive concept will be apparent from the more particular description of preferred embodiments of the inventive concept, as illustrated in the accompanying drawings in which like reference characters refer to the same parts throughout the different views. The drawings are not necessarily to scale, emphasis instead being placed upon illustrating the principles of the inventive concept. In the drawings, the thickness of layers and regions are exaggerated for clarity.

FIG. 1 contains a schematic plan view of an image sensor chip in accordance with some embodiments of the present inventive concept.

FIG. 2 contains a schematic cross sectional view of the image sensor chip in accordance with some embodiments of the present inventive concept, which is taken along line A-A′ of FIG. 1.

FIG. 3 contains a schematic cross sectional view of a camera module in accordance with some embodiments of the present inventive concept.

FIG. 4 contains a schematic cross sectional view of a camera module in accordance with some embodiments of the present inventive concept.

FIG. 5 contains a schematic block diagram of an electronic system employing the camera module in accordance with some embodiments of the present inventive concept.

FIGS. 6 to 9B illustrate steps in a method of manufacturing an image sensor chip, which is shown, for example, in FIGS. 1 and 2, in accordance with some embodiments of the present inventive concept.

### DETAILED DESCRIPTION

Advantages and features of the present inventive concept and methods of accomplishing the same may be understood more readily by reference to the following detailed description of exemplary embodiments and the accompanying drawings. The present inventive concept may, however, be embodied in many different forms and should not be construed as being limited to the embodiments set forth herein. Rather, these embodiments are provided so that this description will be thorough and complete and will fully convey the inventive concept to those skilled in the art, and the present inventive concept will only be defined by the appended claims. In the drawings, sizes and relative sizes of layers and regions may be exaggerated for clarity.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on” another element or layer, the element or layer can be directly on another element or layer, or intervening elements or layers may also be present. In contrast, when an element is referred to as being “directly on” another element or layer, there are no intervening elements or layers present. As used herein, the term “and/or” includes any and all combinations of one or more of the associated listed items.

Spatially relative terms, such as “below”, “beneath”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation, in addition to the orientation depicted in the figures. Throughout the specification, like reference numerals in the drawings denote like elements.

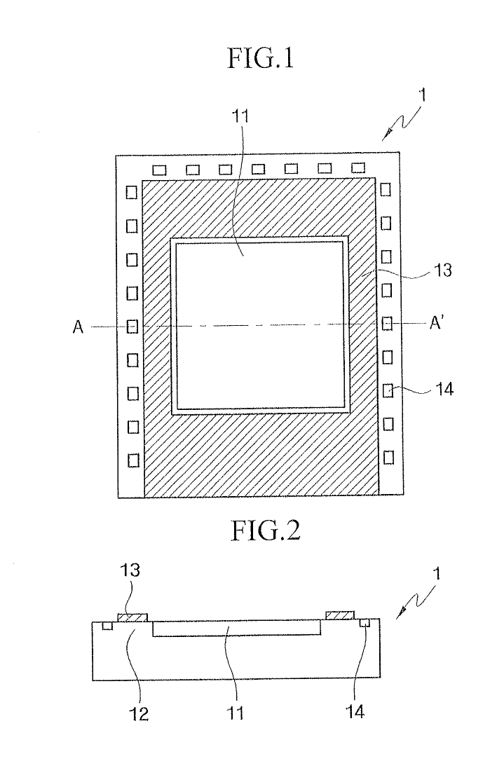

Hereinafter, an image sensor chip in accordance with an exemplary embodiment of the present inventive concept will be described in detail with reference to FIGS. 1 and 2. FIG. 1 illustrates a schematic plan view of an image sensor chip 1 in accordance with some embodiments of the present inventive concept. FIG. 2 illustrates a schematic cross-sectional view of the image sensor chip in accordance with some embodiments of the present inventive concept, which is taken along line A-A′ of FIG. 1.

Referring to FIGS. 1 and 2, an image sensor chip 1 in accordance with embodiments of the present inventive concept includes a light receiving unit 11, also referred to as an active pixel sensor (APS) 11, on which light is incident. A logic unit 12 surrounds the light receiving unit 11. An electromagnetic wave shielding layer 13 is formed on the logic unit 12, but is not formed on the light receiving unit 11. That is, the electromagnetic wave shielding layer 13 is formed on the logic unit 12, excluding the light receiving unit 11. Connection pads 14 are disposed and arranged at an edge portion of the logic unit 12 and the like.

The image sensor chip 1 may be or may include a complementary metal oxide semiconductor (CMOS) image sensor chip or a charge coupled device (CCD) image sensor chip. The CCD image sensor chip is based on an analog circuit and employs a method in which incident light is distributed to plural cells. The cells store electric charges of the incident light. Brightness is determined based on the magnitude of the electric charges. A converter is used to represent colors. The CCD image sensor chip can provide clear image quality, but requires high data storage capacity and causes high power consumption. Accordingly, the CCD image sensor chip is widely used in digital cameras requiring high image quality. The CMOS image sensor chip includes analog and digital signal processing circuits integrated in a semiconductor chip. The power consumption of the CMOS image sensor chip is only one tenth of the power consumption of the CCD image sensor chip. The CMOS image sensor chip is configured as one chip to enable the manufacture of a small-sized product. As such, the CMOS image sensor is widely used in small portable devices such as digital cameras, camera phones, personal media players (PMP) and the like.

As illustrated in FIG. 1, the light receiving unit 11 on which light is incident may be arranged in a central portion of the image sensor chip 1. The light receiving unit 11 may include a plurality of pixels. Each pixel includes a photoelectric conversion device for detecting incident light and converting the incident light into a signal charge and a transistor for performing charge amplification, switching and the like to generate a signal charge corresponding to the amount of light received.

In some embodiments, the logic unit 12 is arranged to surround the light receiving unit 11. The logic unit 12 may include a driving circuit for driving the pixels, an analog-digital converter (ADC) for converting a signal charge into a digital signal, an image sensor processor (ISP) for forming an image signal using a digital signal and other such circuitry for forming an image signal.

In some embodiments, the connection pads 14 are arranged at an edge portion of the logic unit 12. The connection pads 14 are electrically connected to the pixels of the light receiving unit 11 and electrically connected to an external circuit. The connection pads 14 may have a rectangular plate shape and may be formed of a conductive metal material such as gold (Au), silver (Ag), copper (Cu), chromium (Cr), aluminum (Al), tin (Sn), lead (Pb), titanium (Ti), or an alloy thereof.

The electromagnetic wave shielding layer 13 is formed on the logic unit 12. The electromagnetic wave shielding layer 13 serves to shield the logic unit 12 from electromagnetic waves inputted/outputted through a lens unit (described below in detail) without the need for shielding by a housing of a camera module or the like. In some embodiments, the electromagnetic wave shielding layer 13 is formed on a region of the logic unit 12 excluding the light receiving unit 11. That is, the shielding layer 13 is formed over the logic unit 12 but is not formed over the light receiving unit 11. In general, the logic unit 12 processes a larger amount of data than the light receiving unit 11 and performs a relatively fast operation. As a result, the logic unit 12 is more easily influenced by electromagnetic interference (EMI). Accordingly, the electromagnetic wave shielding layer 13 is formed on the logic unit 12. Further, the electromagnetic wave shielding layer 13 is not formed on the connection pads 14 and exposes the connection pads 14.

In some embodiments, the electromagnetic wave shielding layer 13 may contain a soft magnetic material or metal powder. The soft magnetic material or metal powder shields electromagnetic waves to reduce the noise of a signal. The soft magnetic material may contain ferrite (e.g., Mn—Zn ferrite, Ni—Zn ferrite or the like). The metal powder may contain powder of conductive metal, e.g., titanium (Ti), chromium (Cr), titanium tungsten (TiW), aluminum (Al), nickel (Ni), copper (Cu), silver (Ag), and/or an alloy thereof.

The electromagnetic wave shielding layer 13 may be formed, for example, by coating a soft magnetic material or a material containing metal powder on the logic unit 12, or by attaching a film formed of a soft magnetic material or a material containing metal powder onto the logic unit 12. The electromagnetic wave shielding layer 13 is not formed on the light receiving unit 11 and, thus, may have some degree of opacity or opaqueness. That is, since the electromagnetic wave shielding layer 13 is not formed on the light receiving unit 11, it will not be in the path of propagating incident light that is to be detected. Therefore, it need not be transparent to the propagating incident light.

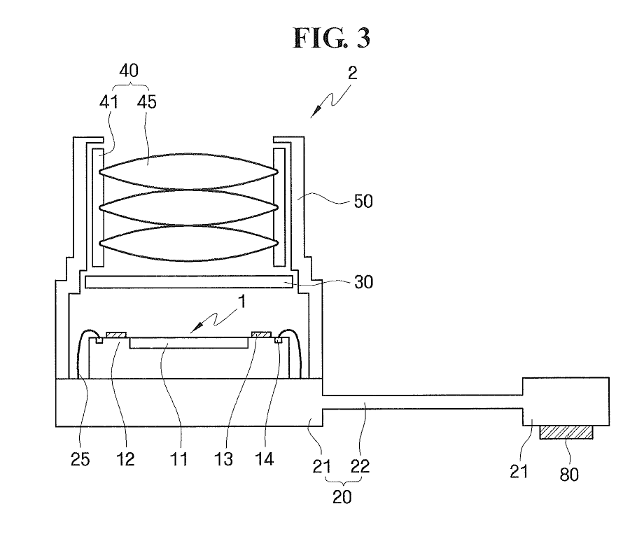

A camera module in accordance with some embodiments of the present inventive concept will be described with reference to FIG. 3. FIG. 3 illustrates a schematic cross-sectional view of a camera module 2 in accordance with some embodiments of the present inventive concept.

Referring to FIG. 3, a camera module 2 in accordance with some embodiments of the present inventive concept includes a lens unit 40 having lenses 45, the image sensor chip 1 on which light having passed through the lens unit 40 is incident, a housing 50 enclosing the side surfaces of the image sensor chip 1 and the lens unit 40, a printed circuit board (PCB) 20 mounted with the image sensor chip 1, and a connector 80. In some embodiments, the image sensor chip 1 can be, for example, the image sensor chip 1 described above in detail.

The lens unit 40 includes one or more lenses 45 and a lens barrel 41 for fixing the lenses 45. The lenses 45 are formed of a transparent material such as glass in a spherical shape or non-spherical shape, and converge or diffuse incident light to form an optical image. The camera module 2 may include a plurality of the lenses 45, and the lenses 45 may be fixed in the lens barrel 41.

A plastic lens and/or glass lens may be used as the lenses 45. The plastic lens may be manufactured by mass production at a low unit production cost via injection molding. The glass lens may realize a megapixel high resolution. The lens unit 40 may have various combination structures according to the desired optical characteristics of the camera module. In the embodiments of the present inventive concept, the structure of the lens unit 40 is shown in the drawings as a relatively simple structure for purposes of each and clarity of illustration and description. It will be understood that various combinations and types of lenses 45 may be used, according to the inventive concept.

The image sensor chip 1 has been described in detail above with reference to FIGS. 1 and 2. As described above, the electromagnetic wave shielding layer 13 serves to shield electromagnetic waves inputted/outputted through the lens unit 40.

The range of wavelengths of light that are visible to the human eye is about 400 nm to about 700 nm. The image sensor of the inventive concept detects light having a wavelength of about 380 nm to about 1,000 nm. Accordingly, the image sensor is more sensitive to infrared light, i.e., above 700 nm, than human eyes. Accordingly, an infrared cut filter (IR cut filter) 30 may be positioned in a path of light that has passed through the lens unit 40 and is incident on the image sensor chip 1. The IR cut filter 30 cuts off light in an infrared wavelength region before the image information is transmitted to the image sensor, which is more sensitive to infrared light than the human eye. As a result, color reproducibility is enhanced according to some embodiments.

The image sensor chip 1 is mounted on the printed circuit board 20. The printed circuit board 20 may include an insulating plate having one surface on which a circuit wiring pattern is formed using copper or other such conductive material. The surface having the wiring pattern may be formed by laminating multiple layers. The printed circuit board 20 may be a rigid flexible printed circuit board (rigid FPCB) 20. Hereinafter, a case in which the printed circuit board 20 is a rigid flexible printed circuit board will be described by way of example. It will be understood that the inventive concept is not limited to a rigid FPCB configuration.

The rigid flexible printed circuit board 20 includes a rigid region 21 and a flexible region 22. It can be understood that the rigid region 21 and the flexible region 22 are distinguished from each other by a relative difference of flexibility rather than an absolute difference of flexibility. The flexible region 22 provides flexibility when the rigid flexible printed circuit board 20 is bent, for example, when the rigid flexible printed circuit board 20 is inserted into a part or the like. The number of laminated insulating plates having the wiring pattern in the rigid region 21 may be greater than that in the flexible region 22. It should be noted that in FIG. 3, the two indicated thicker portions of the rigid flexible printed circuit board 20 are both portions of the rigid region 21.

The image sensor chip 1 may be mounted on the rigid region 21 of the rigid flexible printed circuit board 20. In some embodiments, the image sensor chip 1 may be mounted on the rigid flexible printed circuit board 20 by using a through-silicon via (TSV) approach. Alternatively, the image sensor chip 1 may be mounted by using a wire bonding method using wires 25, as illustrated in FIG. 3. The wires 25 may be connected to the connection pads 14 exposed by the electromagnetic wave shielding layer 13.

The housing 50 encloses the side surfaces of the lens unit 40 and the image sensor chip 1. An opening for introducing light to the lens unit 40 is formed at an upper side of the housing 50. The housing 50 may be formed of epoxy, alkyd or silicone resin or other similar material. The housing 50 may be manufactured by, for example, injection molding.

The connector 80 for applying an external signal to the camera module 2 may be attached to one end of the rigid flexible printed circuit board 20. The connector 80 may be attached to the rigid region 21.

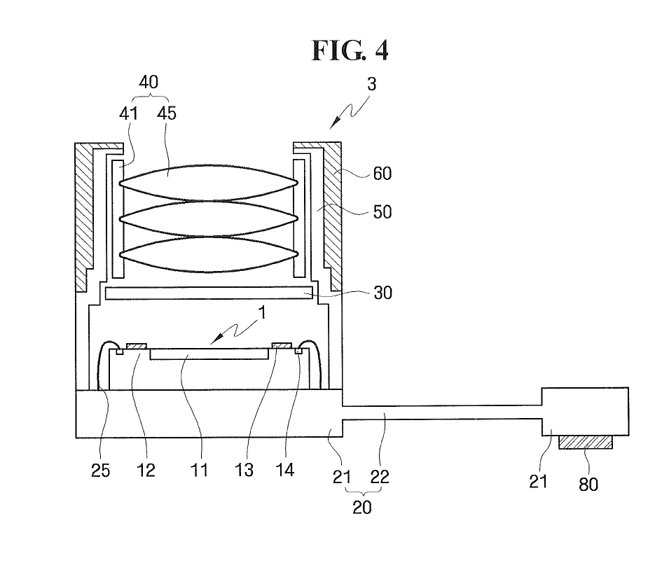

A camera module in accordance with another embodiment of the present inventive concept will be described with reference to FIG. 4. FIG. 4 illustrates a schematic cross-sectional view of the camera module 3 in accordance with another embodiment of the present inventive concept.

Referring to FIG. 4, a camera module 3 in accordance with another embodiment of the present inventive concept is different from the camera module 2 in accordance with the embodiment of the present inventive concept described in detail above in that the camera module 3 further includes a metal cover 60 enclosing a sidewall of the housing 50. The other elements of the camera module 3 are the same as the like elements of the camera module 2. Therefore, detailed description of those elements will not be repeated. The metal cover 60 may serve to, for example, shield external electromagnetic waves. The metal cover 60 may be formed of a conductive metal material such as titanium (Ti), chromium (Cr), titanium tungsten (TiW), aluminum (Al), nickel (Ni), copper (Cu), silver (Ag), and an alloy thereof. By using the metal cover 60 in addition to the electromagnetic wave shielding layer 13, it is possible to more effectively prevent electromagnetic interference (EMI) that may occur in the camera module 3.

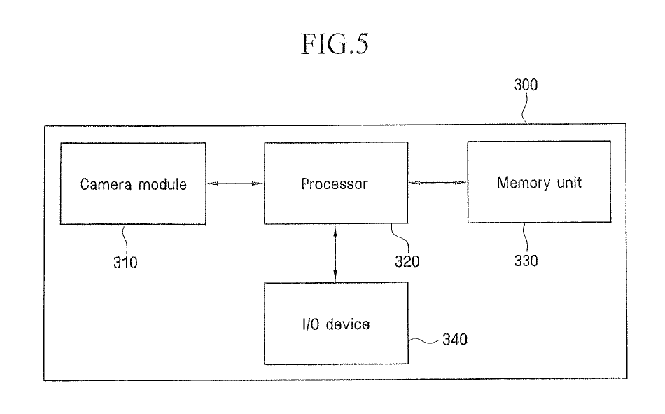

FIG. 5 is a schematic block diagram of an electronic system which incorporates a camera module in accordance with any of the embodiments of the present inventive concept.

Referring to FIG. 5, the electronic system 300 according to embodiments of the inventive concept may include a camera module 310 for capturing an image, a processor 320 for performing data processing on the image captured by the camera module 310, a memory unit 330 for storing data of the image obtained by performing data communication with the processor 320, and an input/output device 340 for performing data communication with the processor 320. In this case, the electronic system 300 may be, for example, a cellular telephone, a digital camera, a digital video camera or a portable notebook computer.

The camera module 310 may be any of the embodiments of camera modules described herein in detail. That is, the camera module 310 may include the camera modules described in detail with reference to FIGS. 3 and 4. Although not shown in FIG. 5, an image signal captured by the camera module 310 may be converted into digital data by a signal processing circuit, e.g., an analog/digital (A/D) conversion circuit. The converted digital image data generated by the A/D conversion circuit from the image signal captured by the camera module 310 can then be transmitted to the processor 320.

The processor 320 may perform various data processes on the digital image data. In this case, the digital image data may be temporarily stored in a rewritable semiconductor memory, e.g., a non-volatile memory, and data processing may be performed on the converted image data. The processed image data may be stored in the memory unit 330. The memory unit 330 may include a rewritable semiconductor memory, e.g., a non-volatile memory, and the processed image data may be stored in the non-volatile memory. The non-volatile memory may employ a flash memory card.

The electronic system 300 may exchange image data with another electronic system, such as a personal computer or computer network, through the input/output device 340. For example, the image data processed by the processor 320 may be outputted to an external apparatus, e.g., an external display, a personal computer and/or a printer, connected to the input/output device 340. Further, the input/output device 340 may provide the image data to a wireless transmission/reception antenna, a high speed digital transmission line or a peripheral bus line of a computer or the aforementioned cellular telephone or the like. Image data communication between the camera module 310, the processor 320, the memory unit 330 and the input/output device 340 may be performed using any appropriate bus architectures.

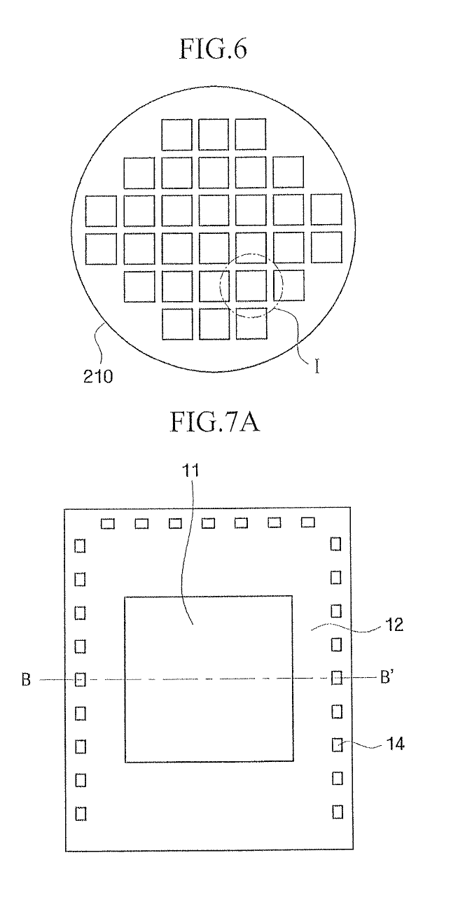

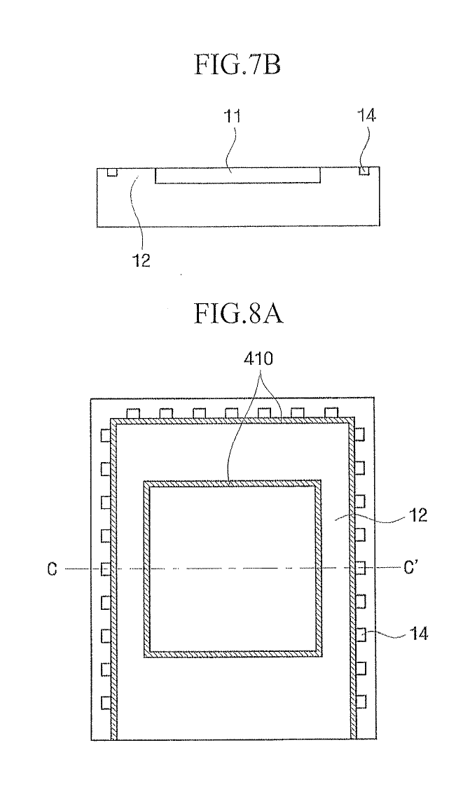

FIGS. 6 to 9B illustrate steps in a method of manufacturing an image sensor chip, such as the image sensor chip shown in FIGS. 1 and 2, in accordance with embodiments of the present inventive concept. A method of manufacturing an image sensor chip, such as the image sensor chip shown in FIGS. 1 and 2, in accordance with embodiments of the present inventive concept, will be described in detail with reference to FIGS. 1, 2, and 6 to 9B. FIGS. 7A to 9B illustrate schematic enlarged plan views and schematic cross-sectional views of a portion of the image sensor chip indicated by a dashed circle I of FIG. 6. Specifically, FIGS. 7A, 8A and 9A are the plan views, and FIGS. 7B, 8B and 9B are the cross-sectional views, which are taken along lines B-B′, C-C′ and D-D′, respectively, of FIGS. 7A, 8A and 9A, respectively.

Referring to FIGS. 6, 7A and 7B, a wafer 210 for an image sensor is prepared. That is, the image sensor wafer 210 on which the light receiving unit 11, the logic unit 12 and the connection pads 14 of an image sensor, as described above in detail, have been formed is prepared. For the purpose of clarity of the description, the following description is made for a single unit chip. It will be understood that this detailed description is applicable to any number of chips formed simultaneously or at different times during different process steps.

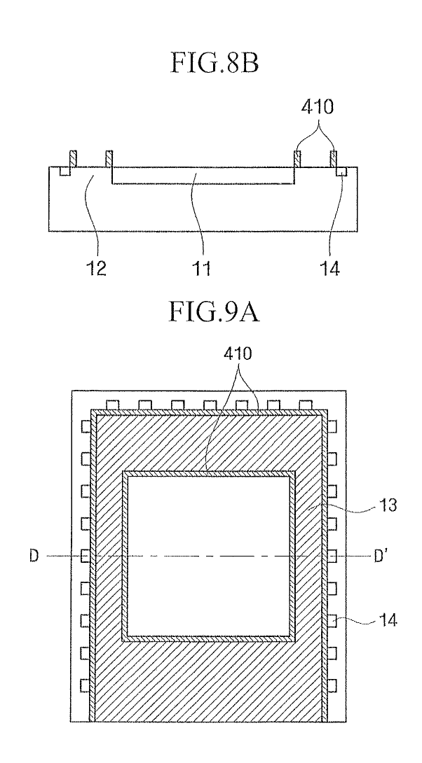

Referring to FIGS. 8A and 8B, a DAM 410 is formed outside of and around or outwardly around the light receiving unit 11 and inside of and around or inwardly around a region where the connection pads 14 are formed. The DAM 410 serves to prevent a material for forming an electromagnetic wave shielding layer subsequently formed as a coating on the logic unit 12 from being formed on the light receiving unit 11 and the connection pads 14. The DAM 410 may be formed of resin such as polyimide or similar material.

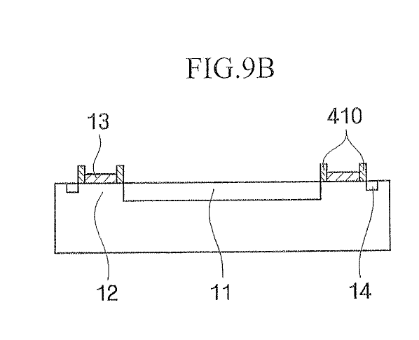

Referring to FIGS. 9A and 9B, the electromagnetic wave shielding layer 13 is formed on the logic unit 12 by applying a coating material on the logic unit 12, The coating material being used in forming the electromagnetic shielding layer 13 on the logic unit 12. The electromagnetic wave shielding layer 13 may be formed by applying a coating of, for example, a soft magnetic material or a material containing metal powder on the logic unit 12. The soft magnetic material or material containing metal powder may be applied by, for example, a spin coating method, a slit coating method, a spraying method, a screen printing method, an ink-jet printing method, a gravure printing method, an off-set printing method, a dispensing method or other such method. The DAM 410 formed outwardly around the light receiving unit 11 and inwardly around a region where the connection pads 14 are formed prevents the material for forming the electromagnetic wave shielding layer 13 from being introduced into the light receiving unit 11 and the connection pads 14. As a result, the electromagnetic wave shielding layer 13 is formed to expose the light receiving unit 11 and the connection pads 14.

Subsequently, referring to FIGS. 1 and 2, the DAM 410 is removed.

A method of manufacturing the image sensor chip shown in FIGS. 1 and 2 in accordance with another embodiment of the present inventive concept will be described in detail with reference to FIGS. 1 and 2.

In the method of manufacturing the image sensor chip in accordance with this other embodiment of the present inventive concept, the electromagnetic wave shielding layer 13 is formed by attaching a film made of a material for forming an electromagnetic wave shielding layer onto the logic unit 12. The film made of a material for forming an electromagnetic wave shielding layer may include openings corresponding to the light receiving unit 11 and the connection pads 14 such that the electromagnetic wave shielding layer 13 is not formed on the light receiving unit 11 and the connection pads 14. The film made of a material for forming an electromagnetic wave shielding layer may be attached onto the logic unit 12 by, for example, die attach equipment.

While the present inventive concept has been particularly shown and described with reference to exemplary embodiments thereof, it will be understood by those of ordinary skill in the art that various changes in form and detail may be made therein without departing from the spirit and scope of the present inventive concept as defined by the following claims.

What is claimed is:

1. An image sensor chip, comprising:
a light receiving unit formed in the image sensor chip, the light receiving unit being adapted to receive incident light;
a logic unit formed in the image sensor chip, the logic unit being formed to surround the light receiving unit; and
an electromagnetic wave shielding layer formed on the logic unit to surround the logic unit and to be absent from a region of the image sensor chip above the light receiving unit.

2. The image sensor chip of claim 1, wherein the electromagnetic wave shielding layer comprises a soft magnetic material.

3. The image sensor chip of claim 2, wherein the soft magnetic material comprises ferrite.

4. The image sensor chip of claim 1, wherein the electromagnetic wave shielding layer comprises metal powder.

5. The image sensor chip of claim 1, further comprising connection pads arranged at an edge portion of the logic unit, the electromagnetic wave shielding layer exposes the connection pads.

6. The image sensor chip of claim 1, wherein the electromagnetic wave shielding layer is formed by applying a material for forming an electromagnetic wave shielding layer as a coating on the logic unit.

7. The image sensor chip of claim 1, wherein the electromagnetic wave shielding layer is formed by attaching a film made of a material for forming an electromagnetic wave shielding layer onto the logic unit.

8. A camera module, comprising:
a lens unit including a lens; and
an image sensor chip which includes a light receiving unit configured such that light passing through the lens unit is incident on the light receiving unit, a logic unit provided to surround the light receiving unit, and an electromagnetic wave shielding layer formed on the logic unit to surround the logic unit and to be absent from a region of the image sensor chip above the light receiving unit.

9. The camera module of claim 8, wherein the electromagnetic wave shielding layer comprises a soft magnetic material.

10. The camera module of claim 8, wherein the electromagnetic wave shielding layer comprises metal powder.

11. The camera module of claim 8, further comprising a housing enclosing side surfaces of the lens unit and the image sensor chip.

12. The camera module of claim 11, further comprising a metal cover enclosing the housing.

13. The camera module of claim 8, further comprising a printed circuit board on which the image sensor chip is mounted.

14. The camera module of claim 13, wherein the printed circuit board is a rigid flexible printed circuit board (rigid FPCB) including a rigid region and a flexible region.

15. A portable electronic device with a camera, comprising:
an opening for allowing light to pass into the camera;
a camera module for receiving the light, the camera module comprising:
a lens through which the light passes, and
an image sensor chip, the light passing through the lens being incident on the image sensor chip, the image sensor chip including a light receiving unit on which the light is incident, a logic unit surrounding the light receiving unit, and an electromagnetic wave shielding layer formed on the logic unit to surround the logic unit and to be absent from a region of the image sensor chip above the light receiving unit;
a processor for performing data processing on an image captured by the camera module; and
a memory unit in communication with the processor for storing data of the image.

16. The portable electronic device of claim 15, further comprising an input/output device in communication with the processor for exchanging the data with an external device.

17. The portable electronic device of claim 15, wherein the portable electronic device is a cellular telephone.

18. The portable electronic device of claim 15, wherein the portable electronic device is a digital camera.

19. The portable electronic device of claim 15, wherein the portable electronic device is a digital video camera.

20. The portable electronic device of claim 15, wherein the portable electronic device is a portable notebook computer.
